(19) United States
(12) Patent Application Publication
(10) Pub. No.: US 2021/0363640 A1
(43) Pub. Date: Nov. 25, 2021

(54) VACUUM PROCESSING APPARATUS AND SUPPORT SHAFT

(71) Applicant: ULVAC, INC., Chigasaki-shi (JP)

(72) Inventors: Yoshiaki YAMAMOTO, Chigasaki-shi (JP); Yosuke JIMBO, Chigasaki-shi (JP); Takehisa MIYAYA, Chigasaki-shi (JP); Kenji ETO, Chigasaki-shi (JP); Yoichi ABE, Chigasaki-shi (JP)

(21) Appl. No.: 16/958,954

(22) PCT Filed: Jun. 14, 2019
(86) PCT No.: PCT/JP2019/023643

§ 371 Date: Jun. 29, 2020

(30) Foreign Application Priority Data
Jun. 20, 2018 (JP) 2018-117043

(51) Int. Cl. C23C 16/455; C23C 16/509; H01J 37/32

(52) U.S. Cl. CPC C23C 16/45565; C23C 16/509; H01J 2237/3321; H01J 37/32082; H01J 37/3244

(57) ABSTRACT

A vacuum processing apparatus is a vacuum processing apparatus which performs plasma processing and includes an electrode flange, a shower plate, a processing chamber, and a support shaft. The shower plate is provided with a plurality of gas flow paths that are formed therein, and a shaft gas flow path extending in an axial direction of the support shaft is provided at a portion in which the support shaft is connected to the shower plate so that the conductance does not change in an in-plane direction of the shower plate.

### FIELD

The present disclosure relates to a vacuum processing apparatus and a support shaft, and particularly to a technology suitable for use in supporting a shower plate when processing using plasma is performed.

Priority is claimed on Japanese Patent Application No. 2018-117043, filed Jun. 20, 2018, the content of which is incorporated herein by reference.

### BACKGROUND

One of electrical discharge methods used in deposition processes or etching processes is a method using a capacitively coupled plasma (CCP). For example, in a chemical vapor deposition (CVD) apparatus using this method, a cathode and an anode are disposed to face each other, a substrate is disposed on the anode, and electric power is supplied to the cathode. Then, a capacitively coupled plasma is generated between the cathode and the anode and a film is formed on a substrate. Also, as a cathode, there are cases in which a shower plate including a plurality of gas ejection ports is used in order to supply an electrical discharge gas uniformly on a substrate (see, for example, Patent Document 1).

### PRIOR ART DOCUMENTS

### Patent Documents

[Patent Document 1] Japanese Unexamined Patent Application, First Publication No. 2005-328021

### SUMMARY

### Problems to be Solved

However, in the capacitively coupled method using a shower plate, variation in inter-electrode distance (a distance between the cathode and the anode) within a substrate surface may increase as the cathode and the anode become larger. Therefore, variation in film quality of a film formed on the substrate may increase within the substrate surface.

In order to solve this, a shower plate needs to be more firmly supported, but in recent years, use of a nickel based alloy in a chamber has been avoided due to demands for deposition characteristics and particle reduction, and accordingly, there is a concern about insufficient strength in a support portion that supports the shower plate.

As described above, when an area of a support portion and a support area in an in-plane direction of the shower plate are increased in order to maintain a strength of the support portion that supports the shower plate, through holes serving as gas flow paths will be blocked.

In this case, a state in which a gas flow supplied to a substrate side is non-uniform within a surface of the shower plate near the support portion of the shower plate may occur, and thus variation in film quality of the film formed on the substrate within the substrate surface may increase in the portion described above.

Also, a substrate disposed on the anode is placed on a heater in order to obtain a satisfactory film quality. Therefore, since the shower plate reaches a high temperature due to the heat received from the substrate and the heater, thermal deformation of the shower plate may occur due to thermal expansion and a decrease in elastic modulus, and thereby variation in inter-electrode distance within the surface of the shower plate may increase. Therefore, there are cases in which variation in film quality and film thickness distribution of a film formed on the substrate increase within the substrate surface.

In order to prevent occurrence of such a variation, improvement in strength of the support portion of the shower plate is desired.

Furthermore, with regard to the above-described problem, since a shower plate also needs to be enlarged due to an increase in size of a substrate to be processed, improvement in strength of the support portion of the shower plate is further required.

The present disclosure has been made in view of the above circumstances and is intended to achieve the following objectives.
1. Making variation in inter-electrode distance between a cathode and an anode more uniform.
2. Preventing a state in which a gas flow is non-uniform within a surface of a shower plate from occurring.
3. Maintaining a sufficient support strength in the shower plate.
4. Achieving prevention of deterioration in deposition characteristics.
5. Preventing an increase in particle generation.

### Means for Solving the Problems

A vacuum processing apparatus according to a first aspect of the present disclosure is a vacuum processing apparatus that performs plasma processing and includes an electrode flange disposed in a chamber and connected to a high frequency power supply, a shower plate having a first surface facing the electrode flange and a second surface on a side opposite to the first surface, spaced apart from and facing the electrode flange, and serving as a cathode together with the electrode flange, a processing chamber which faces the second surface of the shower plate and in which a substrate to be processed is disposed, and a support shaft connected to the first surface of the shower plate to support the shower plate, wherein the shower plate is provided with a plurality of gas flow paths that are formed therein, allow a space between the electrode flange and the first surface to communicate with the processing chamber, and have a predetermined conductance, and a shaft gas flow path extending in an axial direction of the support shaft is provided at a portion in which the support shaft is connected to the shower plate so that the conductance does not change in the in-plane direction of the shower plate. Therefore, the above-described problem was solved.

In the vacuum processing apparatus according to the first aspect of the present disclosure, a recess may be formed on the first surface of the shower plate, the support shaft may be fitted into the recess, the shaft gas flow path may be provided at a position inside the recess in the support shaft, and the support shaft may have a flow path space positioned above the first surface, provided inside the support shaft, and communicating with the shaft gas flow path, and a radial gas flow path communicating with the flow path space and extending in a radial direction of the support shaft.

In the vacuum processing apparatus according to the first aspect of the present disclosure, with regard to an in-plane density in the in-plane direction of the shower plate, an in-plane density of the shaft gas flow paths may be the same as an in-plane density of the gas flow paths formed around a portion to which the support shaft is connected in the shower plate, and the shaft gas flow path may have the same conductance as the gas flow paths.

In the vacuum processing apparatus according to the first aspect of the present disclosure, with regard to a length in a thickness direction of the shower plate, the length of the shaft gas flow path may be set to be equal to a length of each of the gas flow paths positioned around the support shaft.

In the vacuum processing apparatus according to the first aspect of the present disclosure, a diameter of the shaft gas flow path may be set to be equal to a diameter of the gas flow paths positioned around the support shaft.

In the vacuum processing apparatus according to the first aspect of the present disclosure, the support shaft may be fitted into the recess so that an end portion of the support shaft is spaced apart from a bottom portion in the recess of the shower plate.

The vacuum processing apparatus according to the first aspect of the present disclosure may include an adapter fitted to the end portion of the support shaft, in which the shaft gas flow path may be formed in the adapter.

In the vacuum processing apparatus according to the first aspect of the present disclosure, the recess may be formed on the first surface of the shower plate, a short gas flow path allowing the recess to communicate with the processing chamber may be formed at a bottom portion of the recess of the shower plate, the short gas flow path may include an opening in the recess, the adapter may include a separation distance setting protrusion provided at an end portion of the adapter in the axial direction of the support shaft, and the separation distance setting protrusion may be in contact with the bottom portion of the recess to cause the adapter to be spaced apart from the bottom portion of the recess so that a space is formed between the shaft gas flow path and the opening of the short gas flow path.

In the vacuum processing apparatus according to the first aspect of the present disclosure, the support shaft may include a support angle variable portion which is able to obliquely support the shower plate in response to thermal deformation that occurs when a temperature of the shower plate is raised and lowered.

In the vacuum processing apparatus according to the first aspect of the present disclosure, the support angle variable portion may be a spherical bush provided on both end sides of the support shaft.

A support shaft according to a second aspect of the present disclosure is a support shaft used in a vacuum processing apparatus that performs plasma processing, in which the vacuum processing apparatus includes an electrode flange disposed in a chamber and connected to a high frequency power supply, a shower plate having a first surface facing the electrode flange and a second surface on a side opposite to the first surface, spaced apart from and facing the electrode flange, and serving as a cathode together with the electrode flange, and a processing chamber which faces the second surface of the shower plate and in which a substrate to be processed is disposed, the shower plate is provided with a plurality of gas flow paths that are formed therein, allow a space between the electrode flange and the first surface to communicate with the processing chamber, and have a predetermined conductance, the support shaft is connected to the first surface of the shower plate to support the shower plate, and a shaft gas flow path extending in an axial direction of the support shaft is provided at a portion in which the support shaft is connected to the shower plate so that the conductance does not change in the in-plane direction of the shower plate. Therefore, the above-described problem was solved.

A vacuum processing apparatus according to a first aspect of the present disclosure is a vacuum processing apparatus that performs plasma processing and includes an electrode flange disposed in a chamber and connected to a high frequency power supply, a shower plate having a first surface facing the electrode flange and a second surface on a side opposite to the first surface, spaced apart from and facing the electrode flange, and serving as a cathode together with the electrode flange, a processing chamber which faces the second surface of the shower plate and in which a substrate to be processed is disposed, and a support shaft connected to the first surface of the shower plate to support the shower plate, in which the shower plate is provided with a plurality of gas flow paths that are formed therein, allow a space between the electrode flange and the first surface to communicate with the processing chamber, and have a predetermined conductance, and a shaft gas flow path extending in an axial direction of the support shaft is provided at a portion in which the support shaft is connected to the shower plate so that the conductance does not change in the in-plane direction of the shower plate.

Therefore, even when a thickness of the support shaft is larger than disposition intervals of the gas flow paths, the shower plate can be supported while the conductance of the large number of gas flow paths disposed at positions and a region near the positions, at which the support shaft is mounted to the shower plate, is maintained uniformly in the in-plane direction of the shower plate. Therefore, since a strength of the support shaft can be increased, variation in the inter-electrode distance within the substrate surface can be made more uniform while a state of supporting the shower plate is not deteriorated. At the same time, a uniform state of supplying a gas to a substrate to be processed can be maintained in the in-plane direction of the shower plate, and deposition characteristics, particularly uniformity of film thickness, in the in-plane direction of the substrate can be improved.

In the vacuum processing apparatus according to the first aspect of the present disclosure n, a recess is formed on the first surface of the shower plate, the support shaft is fitted into the recess, the shaft gas flow path is provided at a position inside the recess in the support shaft, and the support shaft includes a flow path space positioned above the first surface, provided inside the support shaft, and communicating with the shaft gas flow path, and a radial gas flow path communicating with the flow path space and extending in a radial direction of the support shaft.

Therefore, the shower plate can be firmly supported by the support shaft fitted into the recess. Also, since the shaft gas flow path is provided, a conductance in the support portion supporting the shower plate and a conductance of the gas flow paths provided around the support portion can be made to be in a uniform state. Therefore, a uniform state of supplying a gas to a substrate to be processed can be maintained in the in-plane direction of the shower plate.

Here, the radial gas flow path preferably has a width and shape of flow path that does not affect the conductance with respect to the shaft gas flow path and the short gas flow path.

In the vacuum processing apparatus according to the first aspect of the present disclosure, with regard to an in-plane density in the in-plane direction of the shower plate, an in-plane density of the shaft gas flow paths is the same as an in-plane density of the gas flow paths formed around a portion to which the support shaft is connected in the shower plate, and the shaft gas flow path has the same conductance as the gas flow paths.

Therefore, since the conductance in the shaft gas flow path is the same as the conductance of the gas flow paths provided around the shaft gas flow path, by simply providing the shaft gas flow path to have the same density as the density in the in-plane direction of the gas flow paths around the mounting position of the support shaft, a uniform state of supplying a gas to a substrate to be processed can be maintained in the in-plane direction of the shower plate.

Here, “an in-plane density of the shaft gas flow paths is the same as an in-plane density of the gas flow paths formed around a portion to which the support shaft is connected in the shower plate” will be described below.

The shower plate includes a short gas flow path and a long gas flow path. The short gas flow path is a flow path provided at a position corresponding to a portion in which a gas flows through the shaft gas flow path. The long gas flow path is positioned around a portion at which the support shaft is mounted to the shower plate. An entire length of the long gas flow path in a thickness of the shower plate is equal to the thickness of the shower plate. Each of the short gas flow path and the long gas flow path opens to the second surface (a surface of the shower plate facing a substrate to be processed) of the shower plate.

In such a structure, the above-described “an in-plane density of the shaft gas flow paths is the same as an in-plane density of the gas flow paths formed around a portion to which the support shaft is connected in the shower plate” has the following two definitions.
(1) The number per unit area of a plurality of short gas flow paths at positions corresponding to the shaft gas flow paths opening to the second surface is equal to the number per unit area of a plurality of long gas flow paths opening to the second surface.
(2) A total opening area per unit area (opening ratio) of the plurality of short gas flow paths at positions corresponding to the shaft gas flow paths opening to the second surface is equal to a total opening area per unit area (opening ratio) of the plurality of long gas flow paths opening to the second surface.

Here, “the shaft gas flow path has the same conductance as the gas flow path” will be described below.

As described above, the shower plate includes the short gas flow path and the long gas flow path. Here, flow paths of a gas flowing from the first surface to the second surface of the shower plate includes a flow path (A) passing through the short gas flow path and a flow path (B) passing through the long gas flow path.

Specifically, a gas between the electrode flange and the shower plate is supplied to the processing chamber via the shaft gas flow path and the short gas flow path provided in the support shaft (flow path (A)). Also, a gas between the electrode flange and the shower plate is supplied to the processing chamber via the long gas flow path (flow path (B)).

In such paths, a definition of “the shaft gas flow path has the same conductance as the gas flow path” described above means that a sum of a conductance in the entire length of the shaft gas flow path and a conductance in the entire length of the short gas flow path is equal to a conductance in the long gas flow path.

Furthermore, in addition to the shaft gas flow path and the short gas flow path, a gas can be supplied to the processing chamber via a flow path that does not affect the conductance. In the vacuum processing apparatus according to the first aspect of the present disclosure, with regard to a length in a thickness direction of the shower plate, a length of the shaft gas flow path is set to be equal to a length of each of the gas flow paths positioned around the support shaft.

Therefore, since a conductance in one shaft gas flow path can be set to be equal to a conductance in the gas flow paths positioned around the support shaft, it is facilitated to set a uniform state of supplying a gas to a substrate to be processed in the in-plane direction of the shower plate.

Here, “a length of the shaft gas flow path is equal to the length of the gas flow paths positioned around the support shaft” will be described below.

This means that a sum of the length of the shaft gas flow path and the length of the short gas flow path (the short gas flow path provided in the shower plate at a position corresponding to the portion in which a gas flows from the shaft gas flow path) which are provided in the support shaft is equal to the length of the long gas flow path provided in the shower plate around the mounting portion of the support shaft.

In the vacuum processing apparatus according to the first aspect of the present disclosure, a diameter of the shaft gas flow path is set to be equal to a diameter of the gas flow paths positioned around the support shaft.

Therefore, the conductance of the shaft gas flow path is easily set to be equal to the conductance of the gas flow paths provided in the shower plate around the mounting portion of the support shaft.

Here, “a diameter of the shaft gas flow path is equal to a diameter of the gas flow paths positioned around the support shaft” will be described below.

This means that a diameter in the entire length of the shaft gas flow path and a diameter in the entire length of the short gas flow path which are provided in the support shaft are each equal to a diameter of the long gas flow path provided in the shower plate around the mounting portion of the support shaft.

In the vacuum processing apparatus according to the first aspect of the present disclosure, the support shaft is fitted into the recess so that an end portion of the support shaft is spaced apart from a bottom portion in the recess of the shower plate.

Therefore, when the support shaft is fitted into the recess, the shaft gas flow path and the short gas flow path can be communicated with each other without performing positional alignment between the shaft gas flow path and the short gas flow path.

Also, a space between the end portion of the support shaft and the bottom portion in the recess preferably has a shape that does not affect the conductance with respect to the shaft gas flow path and the short gas flow path.

Furthermore, in order to set a separation distance between the end portion of the support shaft and the bottom portion in the recess, a separation distance setting protrusion can be provided at the end portion of the support shaft or the bottom portion in the recess.

The vacuum processing apparatus according to the first aspect of the present disclosure includes an adapter fitted to the end portion of the support shaft, in which the shaft gas flow path is formed in the adapter.

Therefore, shape setting of the shaft gas flow path formed in the adapter can be easily performed, and setting of a conductance corresponding to the gas flow paths of the entire shower plate can be easily performed.

Also, when deposition processing conditions are changed or the like, and also when a conductance, an in-plane density, or the like of the gas flow paths is changed, the conductance and the in-plane density can be easily changed by simply replacing the adapter.

In the vacuum processing apparatus according to the first aspect of the present disclosure, the recess is formed on the first surface of the shower plate, a short gas flow path allowing the recess to communicate with the processing chamber is formed at a bottom portion of the recess of the shower plate, the short gas flow path has an opening in the recess, the adapter has a separation distance setting protrusion provided at an end portion of the adapter in the axial direction of the support shaft, and the separation distance setting protrusion is in contact with the bottom portion of the recess to cause the adapter to be spaced apart from the bottom portion of the recess so that a space is formed between the shaft gas flow path and the opening of the short gas flow path.

Therefore, a separation distance between the end portion of the support shaft (the end portion of the adapter) and the bottom portion in the recess can be set by the protrusion (separation distance setting protrusion) in contact with the bottom in the recess. Therefore, the space between the end portion of the support shaft (the end portion of the adapter) and the bottom portion in the recess can be easily set to have a shape that does not affect the conductance of the shaft gas flow path and the short gas flow path.

Furthermore, the separation distance setting protrusion is preferably provided at the end portion of the support shaft or the bottom portion in the recess in order to set a separation distance between the end portion of the support shaft and the bottom portion in the recess.

In the vacuum processing apparatus according to the first aspect of the present disclosure, the support shaft includes a support angle variable portion which is able to obliquely support the shower plate in response to thermal deformation that occurs when a temperature of the shower plate is raised and lowered.

Therefore, even when thermal deformation occurs when a temperature of the shower plate is raised or lowered, the shower plate can be firmly supported without affecting a gas flow generated on the second surface of the shower plate. Therefore, change in a thickness direction of the shower plate is prevented and variation in the inter-electrode distance can be made more uniform.

In the vacuum processing apparatus according to the first aspect of the present disclosure, the support angle variable portion is a spherical bush provided on both end sides of the support shaft.

Therefore, support of the shower plate and thermal deformation prevention thereof can be performed simultaneously.

A support shaft according to a second aspect of the present disclosure is a support shaft used in a vacuum processing apparatus that performs plasma processing, in which the vacuum processing apparatus includes an electrode flange disposed in a chamber and connected to a high frequency power supply, a shower plate having a first surface facing the electrode flange and a second surface on a side opposite to the first surface, spaced apart from and facing the electrode flange, and serving as a cathode together with the electrode flange, and a processing chamber which faces the second surface of the shower plate and in which a substrate to be processed is disposed, the shower plate is provided with a plurality of gas flow paths that are formed therein, allow a space between the electrode flange and the first surface to communicate with the processing chamber, and have a predetermined conductance, the support shaft is connected to the first surface of the shower plate to support the shower plate, and a shaft gas flow path extending in an axial direction of the support shaft is provided at a portion in which the support shaft is connected to the shower plate so that the conductance does not change in the in-plane direction of the shower plate.

Therefore, even when the thickness of the support shaft needs to be set larger than disposition intervals of the gas flow paths in order to set a strength of the support shaft to a predetermined value, the shower plate can be supported while conductance of a plurality of gas flow paths disposed at positions and a region near the positions, at which the support shaft is mounted to the shower plate, is maintained uniformly in the in-plane direction of the shower plate. Therefore, since the strength of the support shaft can be increased, variation in the inter-electrode distance within the substrate surface can be made more uniform while a state of supporting the shower plate is not deteriorated. At the same time, a uniform state of supplying a gas to a substrate to be processed can be maintained in the in-plane direction of the shower plate, and deposition characteristics, particularly uniformity of film thickness, in the in-plane direction of the substrate can be improved.

### Effects

Various effects can be achieved such that variation in the inter-electrode distance is made more uniform, occurrence of a state in which a gas flow is non-uniform within a surface of the shower plate is prevented, a sufficient support strength is maintained in the shower plate, prevention of deterioration in deposition characteristics is achieved, and an increase in particle generation is prevented.

### BRIEF DESCRIPTION OF THE DRAWINGS

FIG. 1 is a schematic cross-sectional view showing a vacuum processing apparatus according to a first embodiment of the present disclosure.

FIG. 2 is a plan view showing a shower plate in the vacuum processing apparatus according to the first embodiment of the present disclosure.

FIG. 3 is a cross-sectional view showing a support shaft in the vacuum processing apparatus according to the first embodiment of the present disclosure.

FIG. 4 is an enlarged cross-sectional view showing the support shaft in the vacuum processing apparatus according to the first embodiment of the present disclosure.

FIG. 5 is a bottom view showing the support shaft in the vacuum processing apparatus according to the first embodiment of the present disclosure.

FIG. 6 is a cross-sectional view showing the support shaft in the vacuum processing apparatus according to the first embodiment of the present disclosure.

FIG. 7 is an enlarged cross-sectional view showing the support shaft in the vacuum processing apparatus according to the first embodiment of the present disclosure.

FIG. 8 is an enlarged cross-sectional view showing a support shaft in a vacuum processing apparatus according to a second embodiment of the present disclosure.

FIG. 9 is a bottom view showing a support shaft in the vacuum processing apparatus according to the second embodiment of the present disclosure.

FIG. 10 is an enlarged cross-sectional view showing the support shaft in the vacuum processing apparatus according to the second embodiment of the present disclosure.

FIG. 11A is a view showing an example according to the present disclosure.

FIG. 11B is a view showing an example according to the present disclosure.

FIG. 11C is a view showing an example according to the present disclosure.

FIG. 11D is a view showing an example according to the present disclosure.

FIG. 12 is a view showing an example according to the present disclosure.

### DETAILED DESCRIPTION

Hereinafter, a vacuum processing apparatus and a support shaft according to a first embodiment of the present disclosure will be described with reference to the drawings.

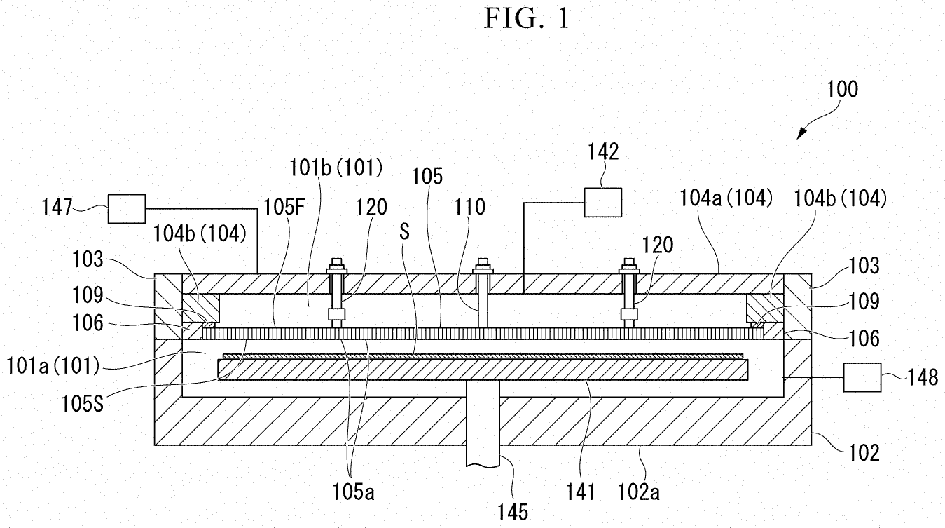

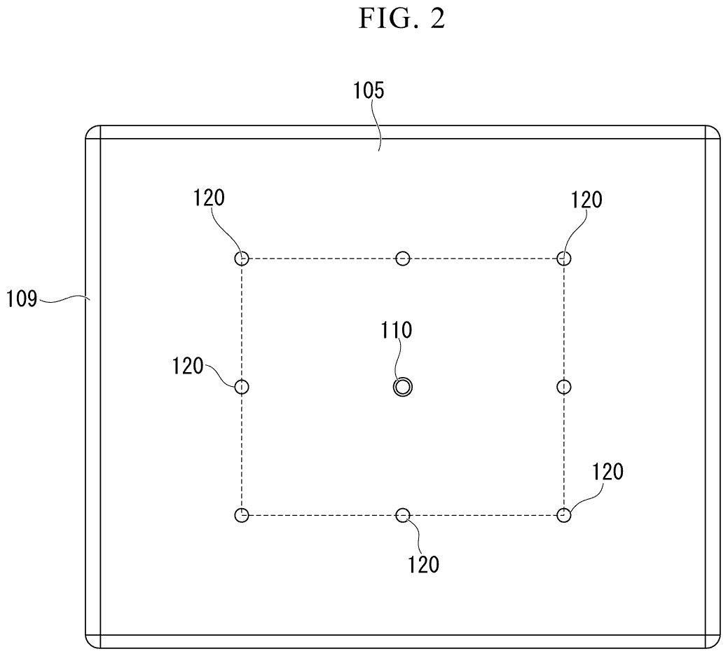

FIG. 1 is a schematic cross-sectional view showing a vacuum processing apparatus according to the present embodiment. FIG. 2 is a top view showing a shower plate of the vacuum processing apparatus according to the present embodiment. In FIG. 1, reference numeral 100 denotes a vacuum processing apparatus.

In the present embodiment, a deposition apparatus using a plasma chemical vapor deposition (CVD) method will be described.

The vacuum processing apparatus 100 according to the present embodiment is an apparatus that carries out deposition using a plasma CVD method and includes a processing chamber 101 having a deposition space 101a serving as a reaction chamber, as shown in FIG. 1. The processing chamber 101 includes a vacuum chamber 102 (chamber), an electrode flange 104 disposed in the vacuum chamber 102, and an insulating flange 103 sandwiched between the vacuum chamber 102 and the electrode flange 104.

An opening is formed in a bottom portion 102a (inner bottom surface) of the vacuum chamber 102. A supporting column 145 is inserted through the opening, and the supporting column 145 is disposed at a lower portion of the vacuum chamber 102. A plate-shaped support portion 141 is connected to a distal end of the supporting column 145 (in the vacuum chamber 102). Also, a vacuum pump (evacuation device) 148 is provided to the vacuum chamber 102 via an evacuation pipe. The vacuum pump 148 reduces a pressure so that the vacuum chamber 102 reaches a vacuum state.

Also, the supporting column 145 is connected to a lifting mechanism (not shown in figures) provided outside the vacuum chamber 102 and is vertically movable in a vertical direction of a substrate S.

The electrode flange 104 includes an upper wall 104a and a circumferential wall 104b. The electrode flange 104 is disposed such that an opening of the electrode flange 104 is positioned on a lower side in a vertical direction of the substrate S. Also, a shower plate 105 is attached to the opening of the electrode flange 104. Therefore, a gas introduction space 101b is formed between the electrode flange 104 and the shower plate 105. Further, the upper wall 104a of the electrode flange 104 faces the shower plate 105. A gas supply device 142 is connected to the upper wall 104a via a gas introduction port.

The gas introduction space 101b functions as a space into which a process gas is introduced. The shower plate 105 includes a first surface 105F facing the electrode flange 104 and a second surface 1055 on a side opposite to the first surface 105F. The second surface 1055 faces the processing chamber 101 and faces the support portion 141. That is, the gas introduction space 101b is a space between the first surface 105F and the electrode flange 104. The space between the second surface 1055 and the support portion 141 forms a part of the deposition space 101a.

The electrode flange 104 and the shower plate 105 are each made of a conductive material.

Specifically, they can be made of aluminum.

A shield cover is provided around the electrode flange 104 to cover the electrode flange 104. The shield cover is not in contact with the electrode flange 104 and is disposed to be continuous with a circumferential edge portion of the vacuum chamber 102. Also, a radio frequency (RF) power supply (high frequency power supply) 147 provided outside the vacuum chamber 102 is connected to the electrode flange 104 via a matching box. The matching box is attached to the shield cover and is grounded to the vacuum chamber 102 via the shield cover.

The electrode flange 104 and the shower plate 105 are configured as a cathode electrode. A plurality of flow paths (gas flow paths) serving as gas ejection ports are formed in the shower plate 105. The flow paths extend in a thickness direction of the shower plate 105 and introduces a process gas from the gas introduction space 101b toward the deposition space 101a. The flow paths provided in the shower plate 105 include gas flow paths 105a (long gas flow paths) having a length equal to a thickness of the shower plate 105 and short gas flow paths 105b which are shorter than the gas flow paths 105a. As will be described below, the short gas flow paths 105b are formed on a bottom surface (bottom portion) 115c of a shaft mounting recess 105c and are open toward the inside of the shaft mounting recess 105c. A process gas introduced into the gas introduction space 101b is ejected from the above-described plurality of flow paths (the gas flow paths 105a and the short gas flow paths 105b) serving as gas ejection ports into the deposition space 101a in the vacuum chamber 102.

The gas flow paths 105a are set to have a substantially uniform separation distance therebetween, that is, the gas flow paths 105a penetrate the entire length in the thickness direction of the shower plate 105 to have a substantially uniform density in the shower plate 105.

The gas flow paths 105a are provided to extend in the thickness direction of the shower plate 105 and are each formed to have a substantially uniform diameter in the radial direction over the entire length in the thickness direction of the shower plate 105. When a conductance of the gas flow paths 105a needs to be set to a predetermined value in order to set an ejection state of a process gas, a structure of the gas flow paths 105a is not limited thereto.

At the same time, the electrode flange 104 and the shower plate 105 that are supplied with power from the RF power supply 147 form a cathode electrode to generate plasma in the deposition space 101a, and processing such as deposition is performed.

As shown in FIG. 2, the shower plate 105 is supported by being suspended from the electrode flange 104 by a substantially rod-shaped fixed shaft (support shaft) 110 and a plurality of deformed shafts (support shafts) 120. Specifically, the fixed shaft 110 and the deformed shaft 120 are connected to the first surface 105F of the shower plate 105.

Also, an insulating shield 106 is provided around an outer position of a circumferential edge portion of the shower plate 105 to be separated from an edge portion of the shower plate 105. The insulating shield 106 is attached to the electrode flange 104 (104b).

A slide seal member 109 is provided around an upper side of the circumferential edge portion of the shower plate 105, and the edge portion of the shower plate 105 is supported by being suspended from the electrode flange 104 by the slide seal member 109.

As shown in FIGS. 1 and 2, the slide seal member 109 is slidable in response to thermal deformation that occurs when a temperature of the shower plate 105 is raised and lowered and electrically connects the circumferential edge portion of the shower plate 105 to the electrode flange 104.

The fixed shaft (support shaft) 110 is fixedly mounted on a center position of the shower plate 105 in a plan view. The deformed shafts 120 (support shafts) are disposed at apexes of a rectangle and midpoints of four sides thereof with the fixed shaft (support shaft) 110 as a center.

The deformed shafts 120 (support shafts) are different from the fixed shaft (support shaft) 110. Each of the deformed shaft 120 is connected to the shower plate 105 by a spherical bush provided at a lower end thereof in response to thermal expansion of the shower plate 105 and can support the shower plate 105 in response to deformation of the shower plate 105 in a horizontal direction.

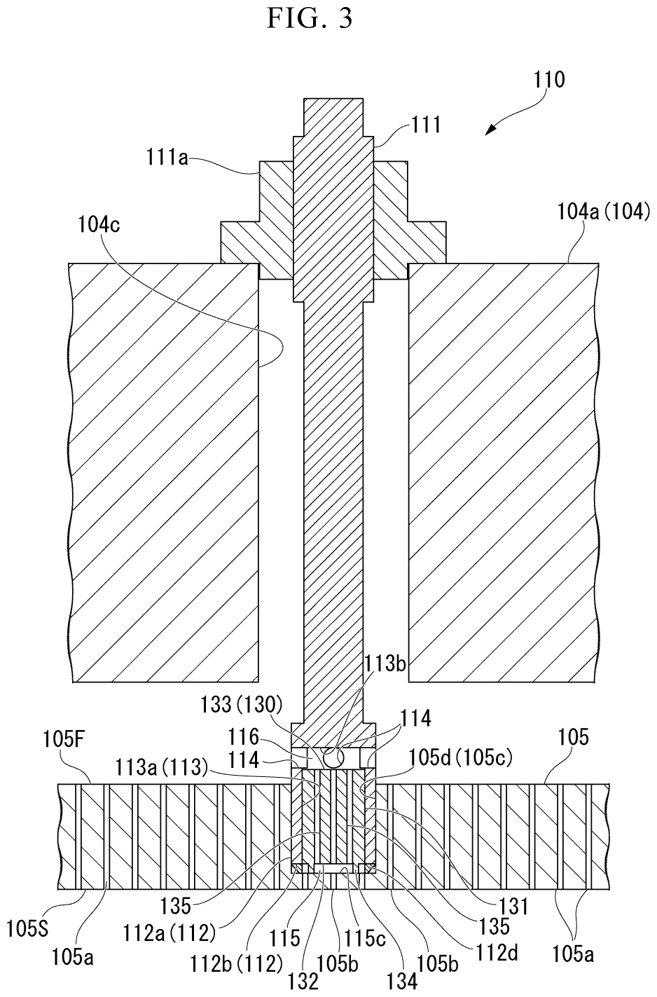

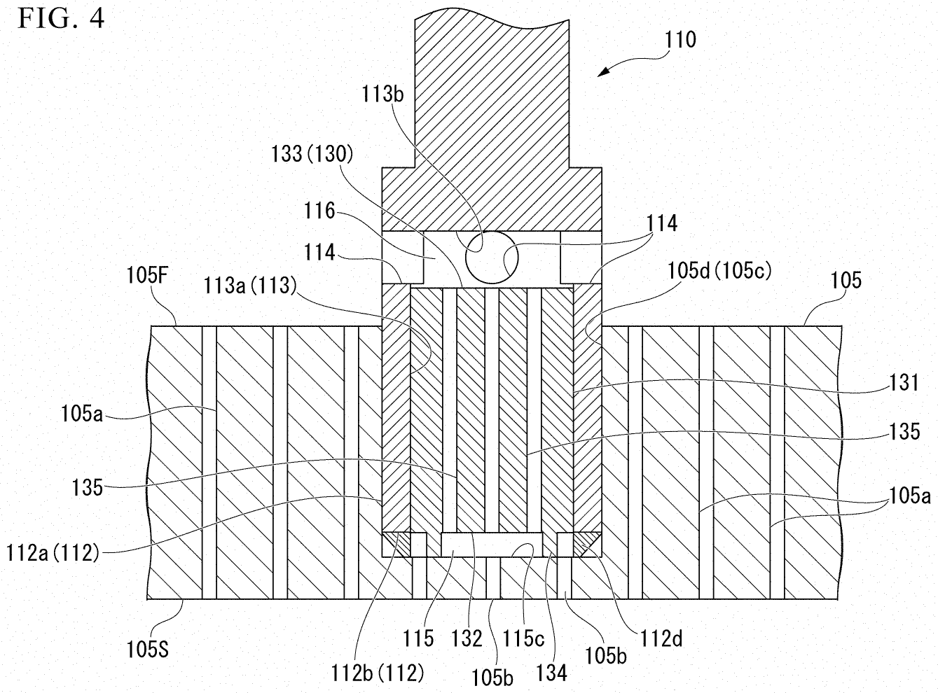

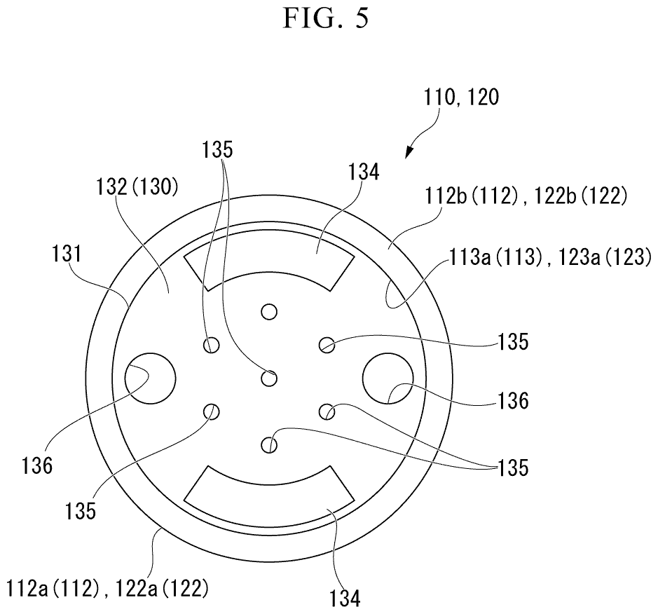

FIG. 3 is a cross-sectional view showing a support shaft of the present embodiment. FIG. 4 is an enlarged cross-sectional view showing a lower end portion of the support shaft of the present embodiment. FIG. 5 is a bottom view of the lower end portion of the support shaft of the present embodiment when viewed from below.

First, the fixed shaft (support shaft) 110 will be described.

As shown in FIGS. 3 to 5, the support shaft 110 according to the present embodiment penetrates the electrode flange 104, an upper end 111 thereof is supported by the electrode flange 104, and a lower end 112 thereof is connected to the shower plate 105.

As shown in FIGS. 3 to 5, the support shaft 110 has a rod shape with a circular cross section and has a length longer than a separation distance between the electrode flange 104 and the shower plate 105 in an axial direction.

At the upper end 111 of the fixed shaft (support shaft) 110, as shown in FIGS. 3 to 5, an upper support member 111a that supports a weight of the fixed shaft (support shaft) 110 and the shower plate 105 is provided around an outer circumferential position thereof in an expanded diameter state.

The upper support member 111a is in a state in which the diameter thereof is expanded compared to that of the fixed shaft (support shaft) 110 and can support the fixed shaft (support shaft) 110 by being placed to close a through hole 104c formed in the electrode flange 104.

As shown in FIGS. 3 to 5, the lower end 112 of the fixed shaft (support shaft) 110 is fitted into a shaft mounting recess (recess) 105c provided on the first surface 105F of the shower plate 105.

The short gas flow paths 105b having substantially the same diameter as the gas flow paths 105a and substantially the same in-plane density as the gas flow paths 105a are formed on the bottom surface (bottom portion) 115c of the shaft mounting recess 105c.

The short gas flow paths 105b penetrate in a thickness direction of the shaft mounting recess 105c of the shower plate 105 to be open to the bottom surface 115c side of the shaft mounting recess 105c and to the support portion (heater) 141 side in the shower plate 105.

A male screw portion is formed on an outer circumferential surface 112a of the lower end 112 of the fixed shaft (support shaft) 110 and is screwed into the shaft mounting recess 105c in which a female screw portion is formed on an inner surface 105d, and thereby the fixed shaft (support shaft) 110 is fixedly connected to the shower plate 105.

As shown in FIGS. 3 to 5, an adapter mounting recess 113 extending in the axial direction is formed in the lower end 112 of the fixed shaft (support shaft) 110 at a center position of an end surface 112b thereof to form a bottomed cylindrical shape. An adapter 130 is fitted and disposed in the adapter mounting recess 113.

Therefore, the end surface 112b of the fixed shaft (support shaft) 110 is configured such that a periphery of the adapter mounting recess 113 is formed in a bottomed cylindrical shape, and a ring-shaped gasket 112d that is in contact with the end surface 112b and the bottom surface 115c is provided on the bottom surface 115c side of the end surface 112b.

The gasket 112d is made of, for example, a metal, and can seal between the end surface 112b and the bottom surface 115c by being pressed and deformed.

The gasket 112d is set so that a diameter of the bottom surface 115c side is reduced compared to that of the end surface 112b side in order to be easily inserted into the shaft mounting recess 105c.

Also, a length in a height direction of the gasket 112d is set to be larger than a separation distance between the end surface 112b and the bottom surface 115c in a state in which the gasket 112d is not sandwiched between the end surface 112b and the bottom surface 115c.

Furthermore, the gasket 112d is not limited to this configuration and other configurations may also be used as long as it is sealable and has temperature resistance.

The adapter mounting recess 113 has an opening that occupies most part of the end surface 112b at the lower end 112 of the support shaft 110 and is formed upward from the opening to have substantially the same diameter and a predetermined length of the support shaft 110 in the axial direction.

A female screw portion is formed on an inner circumferential surface 113a of the adapter mounting recess 113 and can be screwed into a male screw portion formed on an outer circumferential surface 131 of the adapter 130.

An upper end surface 113b is formed at a predetermined position in the axial direction of the support shaft 110 on an upper side of the adapter mounting recess 113, that is, on the upper end 111 side of the support shaft 110. Around the upper end surface 113b, radial gas flow paths 114 to be described below are formed as a plurality of through holes in a radial direction of the support shaft 110 and penetrate to the outside.

As shown in FIGS. 3 to 5, the adapter 130 has a substantially columnar shape, and an upper end surface 133 on the upper end 111 side of the support shaft 110 is positioned in the adapter mounting recess 113 to be spaced apart from the upper end surface 113b of the adapter mounting recess 113.

A gas flow path space 116 is formed between the upper end surface 133 of the adapter 130 and the upper end surface 113b of the adapter mounting recess 113.

Also, the adapter 130 includes a separation distance setting protrusion 134 provided on a lower end surface 132 which is on the lower end 112 side of the support shaft 110 to protrude in the axial direction of the support shaft 110. When the separation distance setting protrusion 134 is in contact with the bottom surface 115c (a surface on which openings of the short gas flow paths 105b are formed) of the shaft mounting recess 105c, the bottom surface 115c of the shaft mounting recess 105c and the lower end surface 132 are spaced apart from each other.

A gas flow path space 115 is formed between the lower end surface 132 of the adapter 130 and the bottom surface 115c of the shaft mounting recess 105c due to the separation distance setting protrusion 134.

Furthermore, the separation distance setting protrusion 134 can also be provided on the bottom surface 115c side of the shaft mounting recess 105c.

Furthermore, as the separation distance setting protrusion 134, a separate member from the shown separation distance setting protrusion 134 with respect to the lower end surface 132 of the adapter 130 or the bottom surface 115c of the shaft mounting recess 105c may be employed. In this case, a configuration in which a ring, a block, or the like having a height equivalent to the separation distance setting protrusion 134 is placed on the bottom surface 115c of the shaft mounting recess 105c can be employed.

As shown in FIGS. 3 to 5, the separation distance setting protrusion 134 may be provided, for example, at two positions to be symmetrical with respect to a center of the lower end surface 132 of the adapter 130 corresponding to an axial position of the support shaft 110. The two separation distance setting protrusions 134 are formed to protrude downward in the axial direction of the support shaft 110 from the lower end surface 132 to have the same length as each other.

A plurality of shaft gas flow paths 135 and 135 are formed in the substantially columnar adapter 130 to penetrate the upper end surface 133 and the lower end surface 132.

The shaft gas flow paths 135 extend in the axial direction of the support shaft 110 so that the conductance does not change in an in-plane direction of the shower plate at portions (the shaft mounting recess 105c) in which the support shafts 110 (the fixed shaft and the deformed shaft) are connected to the shower plate 105. In the support shaft 110, the shaft gas flow paths 135 are provided at a position inside the shaft mounting recess 105c. The support shaft 110 includes the gas flow path space 116 (flow path space) and the radial gas flow paths 114. The gas flow path space 116 is positioned above the first surface 105F, is provided inside the support shaft 110, and communicates with the shaft gas flow paths 135. The radial gas flow paths 114 communicate with the gas flow path space 116 and extend in the radial direction of the support shaft 110.

The shaft gas flow paths 135 each have substantially the same diameter over the entire axial length of the adapter 130 and are formed to have substantially the same cross-sectional shape as the gas flow paths 105a and the short gas flow paths 105b.

A recess 136 is provided on the lower end surface 132 of the adapter 130 at a position spaced apart from the separation distance setting protrusion 134 and the shaft gas flow path 135. The recess 136 can be used as a fitting portion for inserting a tool that rotates the adapter 130 with respect to the support shaft 110 when the adapter 130 is screwed into the adapter mounting recess 113 of the support shaft 110.

In the configuration in which the shower plate 105 is supported by the support shaft 110 in the present embodiment, a process gas introduced into the gas introduction space 101b is supplied to the deposition space 101a through the shower plate 105 as shown in FIGS. 3 to 5. At this time, shapes and structures of the shower plate 105 (the gas flow paths 105a, the short gas flow paths 105b, and the shaft mounting recess 105c) and the support shaft 110 are set so that a first conductance of the gas flow paths 105a when the process gas is ejected from the gas flow paths 105a into the deposition space 101a and a second conductance of flow paths when the process gas is ejected from the support shaft 110 and the short gas flow paths 105b into the deposition space 101a are substantially the same as each other.

Here, the second conductance is a conductance of flow paths when the process gas flows from the gas introduction space 101b to the deposition space 101a through the radial gas flow paths 114, the gas flow path space 116, the shaft gas flow paths 135, the gas flow path space 115, and the short gas flow paths 105b. The second conductance is a conductance that can be obtained by a structure near the lower end 112 of the support shaft 110.

Here, shapes of the radial gas flow paths 114, the gas flow path space 116, and the gas flow path space 115 are all set so that a conductance thereof with respect to the process gas ejected into the deposition space 101a can be ignored. Specifically, cross sections of those flow paths can be formed to be increased to such an extent that fluid resistance to the process gas is negligibly small with respect to the shaft gas flow paths 135 and the short gas flow paths 105b.

Also, a shape of the shaft gas flow path 135 in the support shaft 110 is set and a shape of the short gas flow path 105b in the shower plate 105 is set so that a conductance of the shaft gas flow paths 135 and the short gas flow paths 105b, and a conductance of the gas flow paths 105a at a portion other than the connection portion between the support shaft 110 and the shower plate 105 have substantially the same value as each other.

Specifically, flow path cross-sectional shapes of the shaft gas flow path 135 and the short gas flow path 105b are set to be equal to a flow path cross-sectional shape of the gas flow path 105a. Also, the sum of the length in a flow path direction of the shaft gas flow path 135 and the length in a flow path direction of the short gas flow path 105b is set to be equal to a length in a flow path direction of the gas flow path 105a.

Therefore, a process gas flowing through the following two flow paths is uniformly ejected in the in-plane direction of the shower plate 105.

(Flow path 1) A flow path of a process gas introduced into the gas introduction space 101b, flowing from the radial gas flow paths 114 to the gas flow path space 116, flowing through the shaft gas flow paths 135 in the adapter 130, the gas flow path space 115 in the shaft mounting recess 105c, and the short gas flow paths 105b in the shower plate 105, and then ejected from the short gas flow paths 105b into the deposition space 101a.

(Flow path 2) A flow path of a process gas introduced into the gas introduction space 101b and ejected directly from the gas flow paths 105a of the shower plate 105 into the deposition space 101a.

Furthermore, a sum of the length in a flow path direction of the shaft gas flow paths 135 and the length in a flow path direction of the short gas flow path 105b is set to be equal to the length in a flow path direction of the gas flow path 105a. Therefore, the upper end surface 133 of the adapter 130 can be set to protrude from a surface of the shower plate 105 in the gas introduction space 101b by the same length as a height of the gas flow path space 115.

As a specific method of adjusting the length in a flow path direction, a method of setting a height (a length in the thickness direction of the shower plate 105) of the upper end surface 133 of the adapter 130 by setting a height of the separation distance setting protrusion 134 provided on the lower end surface 132 of the adapter 130, that is, by setting a length of the support shaft 110 in the axial direction can be employed.

At this time, when a rotation angle at the screw portion between the adapter mounting recess 113 and the adapter 130, and a rotation angle at the screw portion between the shaft mounting recess 105c and the lower end 112 are adjusted to each other, a fitting disposition of the adapter 130 into the adapter mounting recess 113 and a fitting disposition of the lower end 112 into the shaft mounting recess 105c can be set.

Next, the deformed shaft (support shaft) 120 will be described.

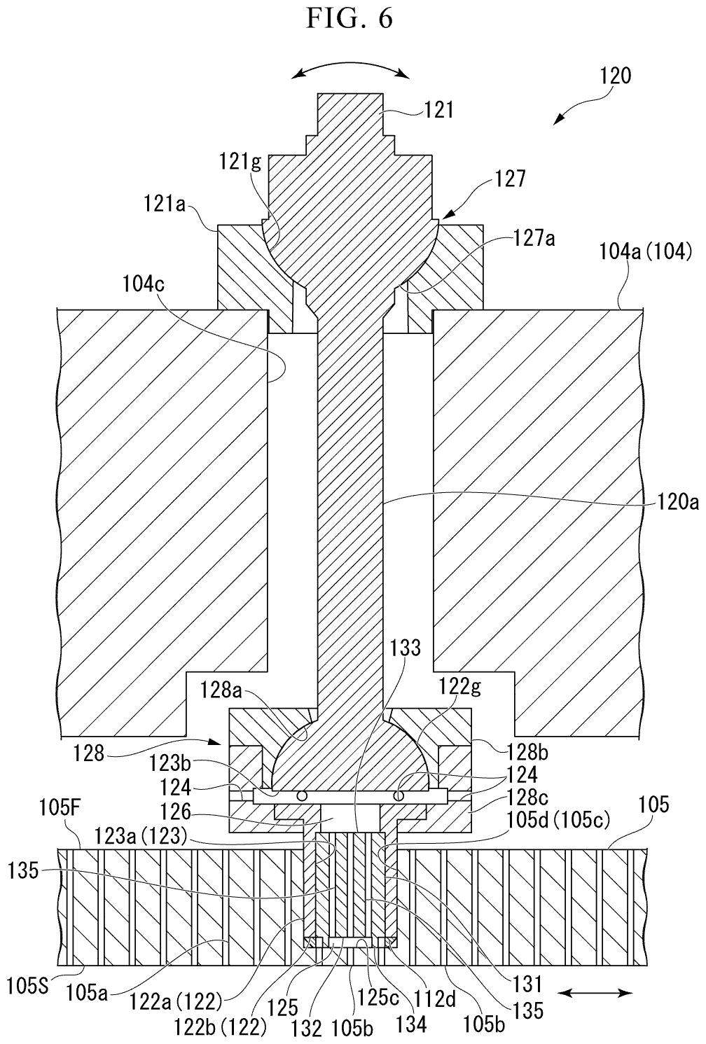

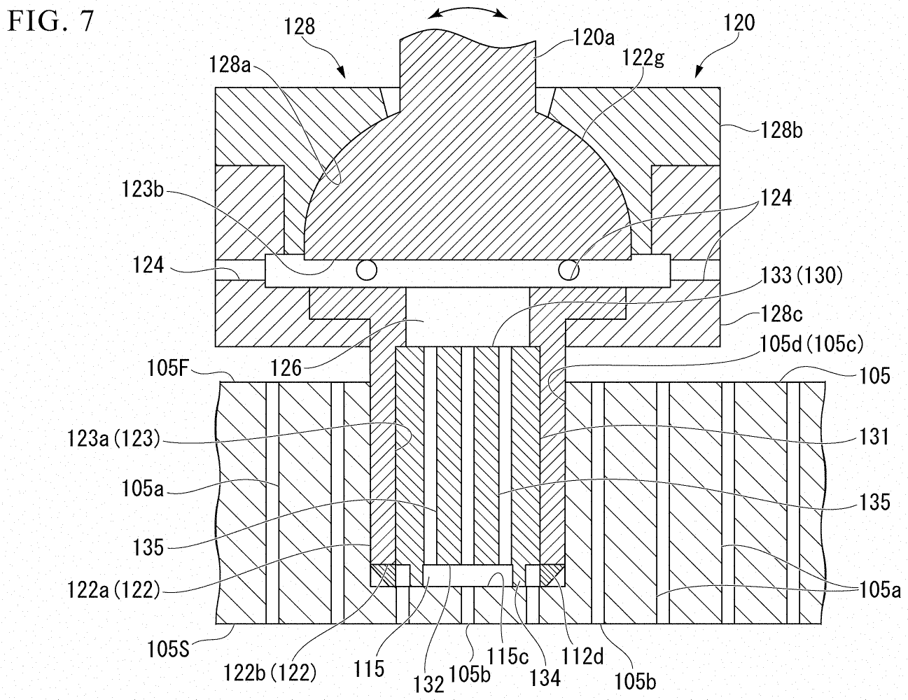

FIG. 6 is a cross-sectional view showing a support shaft in the present embodiment. FIG. 7 is an enlarged cross-sectional view showing a lower end portion of the support shaft in the present embodiment.

As shown in FIGS. 5 to 7, the deformed shaft (support shaft) 120 according to the present embodiment penetrates the electrode flange 104 so that an upper end 121 thereof is supported by the electrode flange 104 and a lower end 122 thereof is connected to the shower plate 105.

As shown in FIGS. 5 to 7, the support shaft 120 has a rod shape with a circular cross section and includes an upper spherical bush portion 127 and a lower spherical bush portion 128 respectively on both end sides (an upper end region and a lower end region) thereof which serve as support angle variable portions.

The support shaft 120 has an axial length longer than a separation distance between the electrode flange 104 and the shower plate 105.

As shown in FIGS. 5 to 7, an upper support member 121a that supports a weight of the deformed shaft (support shaft) 120 and the shower plate 105 is provided around a circumferential position of the upper end 121 of the deformed shaft (support shaft) 120 in an expanded diameter state.

The upper support member 121a serves as the upper spherical bush portion 127, is in a state in which the diameter thereof is expanded compared to a shaft portion 120a which is an intermediate portion of the deformed shaft (support shaft) 120, and can support the fixed shaft (support shaft) 110 by being placed to close the through hole 104c formed in the electrode flange 104.

Also, a spherical surface 127a is formed on an outer circumferential surface of the upper end 121 of the deformed shaft (support shaft) 120 so as to have a downwardly convex shape having a predetermined length in the axial direction.

The spherical surface 127a is in a state in which the diameter thereof is expanded downward in the axial direction with respect to the shaft portion 120a which is an intermediate portion of the deformed shaft (support shaft) 120, and a spherical surface 121g that allows the spherical surface 127a to be slidable is formed in a downwardly concave shape on an axis center side of the upper support member 121a.

A contour diameter of the spherical surface 121g on an axis side of the support shaft 120, that is, on a center side in the radial direction of the shaft portion 120a is set to be larger than a diameter of the spherical surface 127a, and thereby the spherical surface 127a is slidable with respect to the spherical surface 121g along the spherical surface 121g.

Also, while the upper support member 121a is fixed to the electrode flange 104, the shaft portion 120a, which is the intermediate portion of the support shaft 120, forms the upper spherical bush portion 127 that is rockable with respect to the upper support member 121a with a center point of the spherical surface 121g and the spherical surface 127a as a center.

As shown in FIGS. 5 to 7, the lower end 122 of the deformed shaft (support shaft) 120 is fitted into the shaft mounting recess 105c provided in the shower plate 105.

The lower end 122 of the deformed shaft (support shaft) 120 has the same shape as the lower end 112 of the fixed shaft (support shaft) 110, and both of them are fitted into the shaft mounting recess 105c having the same shape.

The short gas flow paths 105b having substantially the same diameter as the gas flow paths 105a and substantially the same in-plane density as the gas flow paths 105a are formed on a bottom surface (bottom portion) 125c of the shaft mounting recess 105c.

The short gas flow paths 105b penetrate in a thickness direction of the shaft mounting recess 105c of the shower plate 105 to be open to a bottom surface 125c side of the shaft mounting recess 105c and to the support portion (heater) 141 side in the shower plate 105.

A male screw portion is formed on an outer circumferential surface 122a of the lower end 122 of the deformed shaft (support shaft) 120 and is screwed into the shaft mounting recess 105c in which a female screw portion is formed on the inner surface 105d, and thereby the deformed shaft (support shaft) 120 is fixedly connected to the shower plate 105.

As shown in FIGS. 5 to 7, an adapter mounting recess 123 extending in the axial direction is formed at the lower end 122 of the deformed shaft (support shaft) 120 at a center position of an end surface 122b thereof to form a bottomed cylindrical shape. The adapter 130 is fitted and disposed in the adapter mounting recess 123.

The adapter mounting recess 123 has an opening that occupies most part of the end surface 122b at the lower end 122 of the support shaft 120 and is formed upward from the opening to have substantially the same diameter and a predetermined length of the support shaft 120 in the axial direction.

A female screw portion is formed on an inner circumferential surface 123a of the adapter mounting recess 123 and can be screwed with a male screw portion formed on the outer circumferential surface 131 of the adapter 130.

The adapter mounting recess 123 penetrates the lower spherical bush portion 128 on an upper side of the adapter mounting recess 123, that is, on the upper end 121 side of the support shaft 120.

On a lower side of the shaft portion 120a, which is an intermediate portion of the deformable shaft (support shaft) 120, the lower spherical bush portion 128 is positioned above the outer circumferential surface 122a on which a male screw portion is formed and is in an expanded diameter state compared to the shaft portion 120a.

The lower spherical bush portion 128 is connected to the lower end 122 mounted in the shower plate 105 so that the shaft portion 120a is rotatable in the axial direction. As the lower spherical bush portion 128, a spherical surface 122g having a shape in which an outer circumference of the shaft portion 120a expands toward the lower end 122 side is formed in an upwardly convex shape at a position on the lower end 122 side of the shaft portion 120a.

The spherical surface 122g is formed in a spherical shape whose diameter is expanded in the axial direction so that a diameter on the lower end 122 side is larger than that on the upper end 121 side of the shaft portion 120a.

A lower spherical bush case portion 128b having a spherical surface 128a corresponding to the spherical surface 122g to be slidable thereon is provided to surround the spherical surface 122g at a radially outward position of the spherical surface 122g.

The spherical surface 128a is formed in an upwardly concave shape.

A contour diameter of the spherical surface 122g on an axis side of the support shaft 120, that is, on a center side thereof is set to be larger than a diameter of the spherical surface 128a, and thereby the spherical surface 128a is slidable with respect to the spherical surface 122g along the spherical surface 122g.

The lower spherical bush case portion 128b is fixed to be integrated with the lower end 122 fitted into the shaft mounting recess 105c via a connection portion 128c.

The connection portion 128c is attached to an upper end position of the adapter mounting recess 123 in the lower end 122 in a flange shape with a diameter expanded than that of the lower end 122, and an upper outer circumferential portion thereof is connected to the lower spherical bush case portion 128b.

Also, the shaft portion 120a, that is the intermediate portion of the support shaft 120, forms the lower spherical bush portion 128 that is rockable with respect to the lower spherical bush case portion 128b and the connection portion 128c with a central point of the spherical surface 122g and the spherical surface 128a as a center.

A contour diameter of the spherical surface 122g on an axis side of the support shaft 120, that is, on a center side in the radial direction of the shaft portion 120a is set to be larger than a diameter of the spherical surface 128a. Therefore, the spherical surface 128a is slidable with respect to the spherical surface 122g along the spherical surface 122g.

In the support shaft 120, a lower end surface 123b as an axially inward side of the shaft portion 120a is formed at a lower end position of the spherical surface 128a. The lower end surface 123b is exposed in a gas flow path space 126 to be described below on the adapter mounting recess 123 side.

Around the gas flow path space 126 which is an upper end of the adapter mounting recess 123, radial gas flow paths 124 are formed as a plurality of through holes in the radial direction of the support shaft 120 and penetrate to the outside of the lower spherical bush case portion 128b and the connection portion 128c.

The adapter 130 has the same shape as the adapter fitted into the fixed shaft (support shaft) 110 as shown in FIGS. 5 to 7. The upper end surface 133 which is on the upper end 121 side of the support shaft 120 is positioned in the adapter mounting recess 123 to be spaced apart from the lower end surface 123b of the shaft portion 120a.

The gas flow path space 126 is formed between the upper end surface 133 of the adapter 130 and the lower end surface 123b of the shaft portion 120a.

As will be described below, while the gas flow path space 126 is a process gas flow path, the gas flow path space 126 is also formed as a sliding buffer space so that the lower end surface 123b of the shaft portion 120a does not come into contact with the upper end surface 133 of the adapter 130 or the like when the axis of the shaft portion 120a is obliquely rotated around the vertical axis with respect to the lower spherical bush case portion 128b.

Also, the adapter 130 includes the separation distance setting protrusion 134 provided on the lower end surface 132 which is on the lower end 122 side of the support shaft 120 to protrude in the axial direction of the support shaft 120. When the separation distance setting protrusion 134 is in contact with the bottom surface 125c of the shaft mounting recess 105c, the bottom surface 125c of the shaft mounting recess 105c and the lower end surface 132 are spaced apart from each other.

The gas flow path space 125 is formed between the lower end surface 132 of the adapter 130 and the bottom surface 125c of the shaft mounting recess 105c due to the separation distance setting protrusion 134.

As shown in FIGS. 5 to 7, the separation distance setting protrusion 134 may be provided, for example, at two positions to be symmetrical with respect to the center of the lower end surface 132 of the adapter 130 corresponding to an axial position of the support shaft 120, and both the separation distance setting protrusions 134 have the same length as each other and are formed to protrude downward in the axial direction of the support shaft 120 from the lower end surface 132.

The plurality of shaft gas flow paths 135 are formed in the substantially columnar adapter 130 to penetrate the upper end surface 133 and the lower end surface 132.

The plurality of shaft gas flow paths 135 are provided in a state parallel to each other in the axial direction of the adapter 130, each have substantially the same diameter over the entire axial length of the adapter 130, and are formed to have substantially the same cross-sectional shape as the gas flow paths 105a and the short gas flow paths 105b.

The recess 136 is provided on the lower end surface 132 of the adapter 130 at a position spaced apart from the separation distance setting protrusion 134 and the shaft gas flow path 135. The recess 136 can be used as a fitting portion for inserting a tool that rotates the adapter 130 with respect to the support shaft 120 when the adapter 130 is screwed into the adapter mounting recess 113 of the support shaft 110.

In the configuration in which the shower plate 105 is supported by the support shaft 120 in the present embodiment, a process gas introduced into the gas introduction space 101b is supplied to the deposition space 101a through the shower plate 105 as shown in FIGS. 5 to 7. At this time, shapes and structures of the shower plate 105 (the gas flow paths 105a, the short gas flow paths 105b, and the shaft mounting recess 105c) and the support shaft 120 are set so that the first conductance of the gas flow paths 105a when the process gas is ejected from the gas flow paths 105a into the deposition space 101a and the second conductance of flow paths when the process gas is ejected from the support shaft 120 and the short gas flow paths 105b into the deposition space 101a are substantially the same as each other.

Here, the second conductance is a conductance of the flow paths when the process gas flows from the gas introduction space 101b to the deposition space 101a through the radial gas flow paths 124, the gas flow path space 126, the shaft gas flow paths 135, the gas flow path space 125, and the short gas flow paths 105b. The second conductance is a conductance that can be obtained by a structure on a lower side of the lower spherical bush portion 128 positioned on the lower end 122 side of the support shaft 120.

Here, shapes of the radial gas flow paths 124, the gas flow path space 126, and the gas flow path space 125 are all set so that a conductance thereof with respect to the process gas ejected into the deposition space 101a can be ignored. Specifically, cross sections of those flow paths can be formed to be increased to such an extent that fluid resistance to the process gas is negligibly small with respect to the shaft gas flow paths 135 and the short gas flow paths 105b.

Also, the shape of the shaft gas flow path 135 in the support shaft 120 is set and the shape of the short gas flow path 105b in the shower plate 105 is set so that the conductance of the shaft gas flow paths 135 and the short gas flow paths 105b, and the conductance of the gas flow paths 105a at a portion other than the connection portion between the support shaft 120 and the shower plate 105 have substantially the same value as each other.

Specifically, the flow path cross-sectional shapes of the shaft gas flow path 135 and the short gas flow path 105b are set to be equal to the flow path cross-sectional shape of the gas flow path 105a. Also, a sum of the length in a flow path direction of the shaft gas flow path 135 and the length in a flow path direction of the short gas flow path 105b is set to be equal to the length in a flow path direction of the gas flow path 105a.

Therefore, a process gas flowing through the following two flow paths is uniformly ejected in the in-plane direction of the shower plate 105.

(Flow path 3) A flow path of a process gas introduced into the gas introduction space 101b, flowing from the radial gas flow paths 124 to the gas flow path space 126 in the lower spherical bush portion 128, flowing through the shaft gas flow paths 135 in the adapter 130, the gas flow path space 125 in the shaft mounting recess 105c, and the short gas flow paths 105b in the shower plate 105, and then ejected from the short gas flow paths 105b into the deposition space 101a.

(Flow path 4) A flow path of a process gas introduced into the gas introduction space 101b and ejected directly from the gas flow paths 105a of the shower plate 105 into the deposition space 101a.

Furthermore, a sum of the length in a flow path direction of the shaft gas flow paths 135 and the length in a flow path direction of the short gas flow path 105b is set to be equal to the length in a flow path direction of the gas flow path 105a. Therefore, the upper end surface 133 of the adapter 130 can be set to protrude from the surface of the shower plate 105 in the gas introduction space 101b by the same length as the height of the gas flow path space 115.

As a specific method of adjusting the length in a flow path direction, a height (a lenght in the thickness direction of the shower plate 105) of the upper end surface 133 of the adapter 130 can be set by setting a height of the separation distance setting protrusion 134 provided on the lower end surface 132 of the adapter 130, that is, by setting a length of the support shaft 110 in the axial direction.

At this time, when a rotation angle at the screw portion between the adapter mounting recess 123 and the adapter 130 and a rotation angle at the screw portion between the shaft mounting recess 105c and the lower end 122 are adjusted to each other, a fitting disposition of the adapter 130 into the adapter mounting recess 123 and a fitting disposition of the lower end 122 into the shaft mounting recess 105c can be set.

Next, an operation when a film is formed on a processing surface of the substrate S using the vacuum processing apparatus 100 will be described.

First, the vacuum chamber 102 is depressurized using the vacuum pump 148. In a state in which the inside of the vacuum chamber 102 is maintained at a vacuum, the substrate S is loaded from the outside of the vacuum chamber 102 toward the deposition space 101a. The substrate S is placed on the support portion (heater) 141. The supporting column 145 is pushed upward, and the substrate S placed on the heater 141 also is moved upward. Therefore, a distance between the shower plate 105 and the substrate S is determined as desired to be a distance needed for proper film deposition, and then the distance is maintained.

Thereafter, a process gas is introduced from a process gas supply device 142 (gas supply device) into the gas introduction space 101b through a gas introduction pipe and a gas introduction port. Then, the process gas is ejected from the gas flow paths 105a serving as gas ejection ports of the shower plate 105 and the short gas flow paths 105b corresponding to the support shaft 110 and the support shafts 120 into the deposition space 101a in a uniform state in the in-plane direction of the shower plate 105.

Next, the RF power supply 147 is activated to apply high frequency power to the electrode flange 104.

Then, a high-frequency current flows from a surface of the electrode flange 104 along the surface of the shower plate 105, and electrical discharge is generated between the shower plate 105 and the heater 141. Then, a plasma is generated between the shower plate 105 and the processing surface of the substrate S.

The process gas is decomposed in the plasma generated as described above so that a process gas in a plasma state can be obtained, vapor phase epitaxy reactions occur on the processing surface of the substrate S, and thereby a thin film is formed on the processing surface.

When the above-described processing is performed in the vacuum processing apparatus 100, the shower plate 105 is thermally expanded (thermally deformed), but a support state and a seal state of the shower plate 105 that has been thermally expanded are maintained by the fixed shaft (support shaft) 110 fixedly supporting a central position of the shower plate 105 and by the upper spherical bush portion 127 and the lower spherical bush portion 128 supporting the deformed shafts (support shafts) 120 positioned on the edge portion sides with respect to the fixed shaft (support shaft) 110. Due to the fixed shaft 110 and the deformed shafts 120, occurrence of in-plane variation in inter-electrode distance between the shower plate 105 and the support portion (heater) can be reduced.

Therefore, occurrence of in-plane variation in deposition characteristics such as a film thickness in deposition on the substrate S can be prevented.

At this time, since there is no component that is forced to be deformed by thermal expansion of the shower plate 105, service lives of components can be prolonged.

At the same time, leakage from the gas introduction space 101b to the deposition space 101a through gas flow paths other than the gas flow paths 105a and the short gas flow paths 105b serving as gas ejection ports can be reduced.

Hereinafter, a second embodiment of a vacuum processing apparatus and a support shaft according to the present disclosure will be described with reference to the drawings.

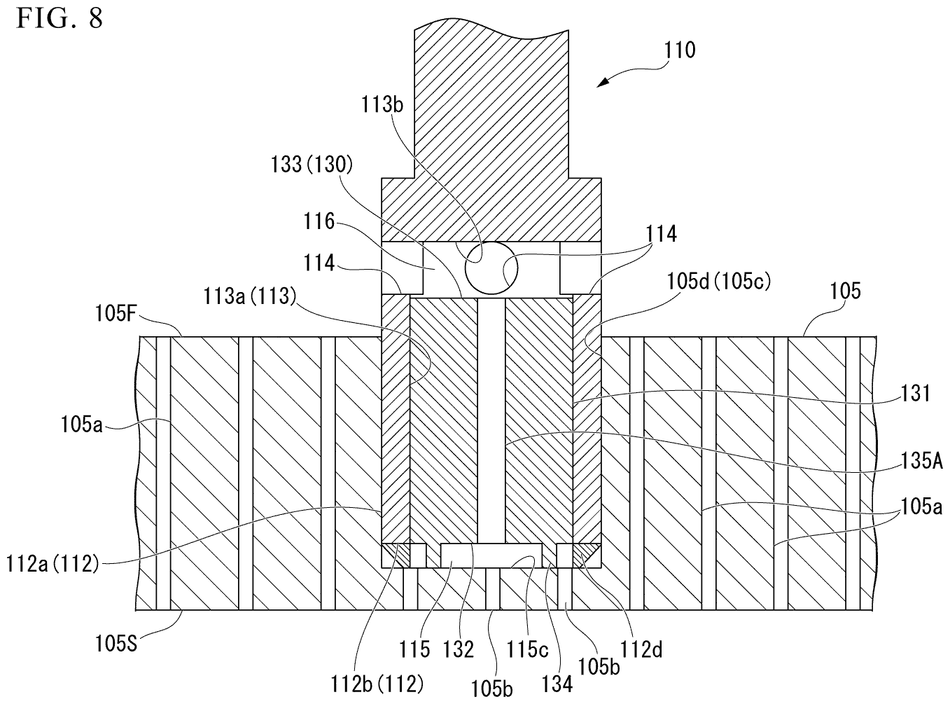

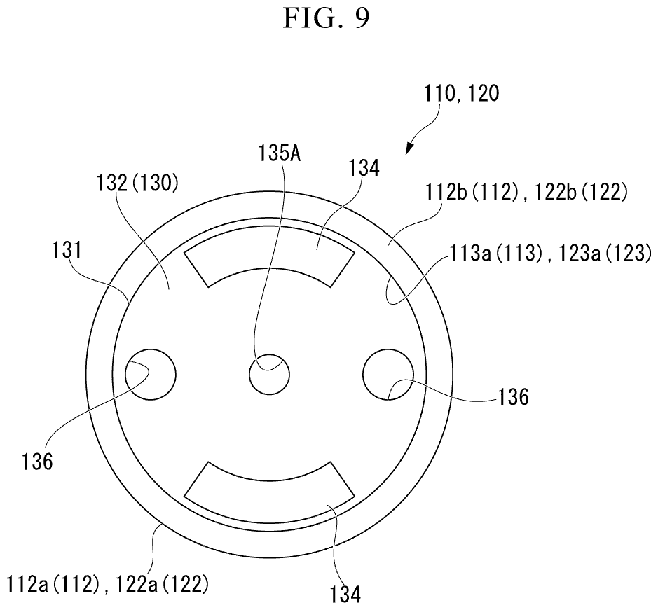

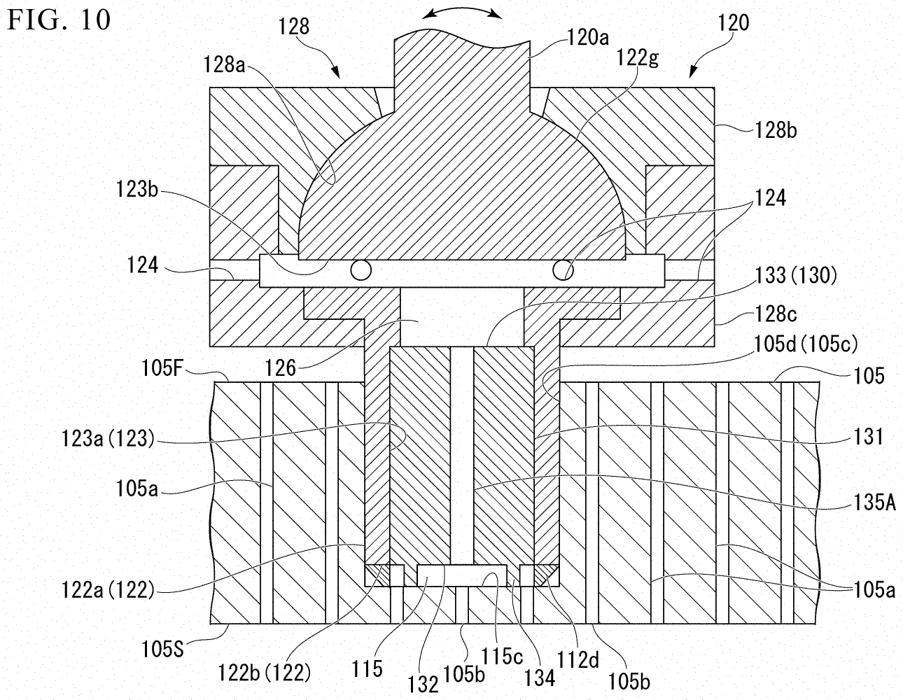

FIG. 8 is an enlarged cross-sectional view showing a lower end portion of the fixed support shaft in the present embodiment. FIG. 9 is a bottom view of a lower end portion of a support shaft in the present embodiment when viewed from below. FIG. 10 is an enlarged cross-sectional view showing a lower end portion of a deformed support shaft in the present embodiment.

The present embodiment is different from the above-described first embodiment in terms of the shaft gas flow path, and the other constituents corresponding to those in the above-described first embodiment will be denoted by the same reference numerals and description thereof will be omitted.

In the present embodiment, as a shape of a shaft gas flow path in a fixed shaft (support shaft) 110, a shape in which only one shaft gas flow path 135A is formed in an adapter 130 is employed. A cross-sectional shape of the shaft gas flow path 135A is not the same as a cross-sectional shape of a gas flow path 105a and is set to have a larger cross-sectional shape (larger diameter) than the gas flow path 105a.

Also in a configuration of the present embodiment in which a shower plate 105 is supported by the fixed shaft (support shaft) 110, a process gas introduced into a gas introduction space 101b is supplied to a deposition space 101a through the shower plate 105 as shown in FIGS. 8 and 9. At this time, shapes and structures of the shower plate 105 (the gas flow paths 105a, short gas flow paths 105b, and a shaft mounting recess 105c) and the shaft gas flow path 135A of the support shaft 110 are set so that a first conductance of the gas flow paths 105a when the process gas is ejected from the gas flow paths 105a into the deposition space 101a and a second conductance of flow paths when the process gas is ejected from the support shaft 110 and the short gas flow paths 105b into the deposition space 101a are substantially the same as each other.

Here, the second conductance is a conductance of flow paths when the process gas flows from the gas introduction space 101b to the deposition space 101a through radial gas flow paths 114, a gas flow path space 116, the shaft gas flow path 135A, a gas flow path space 115, and the short gas flow paths 105b. The second conductance is a conductance that can be obtained by a structure near a lower end 112 of the support shaft 110.

As in the fixed shaft (support shaft) 110 of the first embodiment, shapes of the radial gas flow paths 114, the gas flow path space 116, and the gas flow path space 115 are all set so that conductance thereof with respect to the process gas ejected into the deposition space 101a can be ignored. Specifically, cross sections of those flow paths can be formed to be increased to such an extent that fluid resistance to the process gas is negligibly small with respect to the shaft gas flow path 135A and the short gas flow paths 105b.

Also, a shape of the shaft gas flow path 135 in the fixed shaft (support shaft) 110 is set and a shape of the short gas flow path 105b in the shower plate 105 is set so that conductance of the shaft gas flow path 135A and the short gas flow paths 105b, and a conductance of the gas flow paths 105a at a portion other than the connection portion between the support shaft 110 and the shower plate 105 have substantially the same value as each other.

Specifically, a flow path cross-sectional shape of the short gas flow path 105b is set to be equal to a flow path cross-sectional shape of the gas flow path 105a. Also, a cross-sectional area of the shaft gas flow path 135A can be set to be equal to a sum of cross-sectional areas of the short gas flow paths 105b formed in the shaft mounting recess 105c, and a length in a flow path direction of the shaft gas flow path 135A can be set to be equal to the length in a flow path direction of the shaft gas flow path 135 in the first embodiment.

Accordingly, a sum of the length in a flow path direction of the shaft gas flow path 135A and the length in a flow path direction of the short gas flow path 105b can be set to be equal to the length in a flow path direction of the gas flow path 105a.

Therefore, a process gas flowing through the following two flow paths is uniformly ejected in an in-plane direction of the shower plate 105.

(Flow path 5) A flow path of a process gas introduced into the gas introduction space 101b, flowing from the radial gas flow paths 114 to the gas flow path space 116 near the connection portion between the fixed shaft (support shaft) 110 and the shower plate 105, flowing through the shaft gas flow path 135A in the adapter 130, the gas flow path space 115 in the shaft mounting recess 105c, and the short gas flow paths 105b in the shower plate 105, and then ejected from the short gas flow paths 105b into the deposition space 101a.

(Flow path 6) A flow path of a process gas in which the process gas is introduced into the gas introduction space 101b and ejected directly from the gas flow paths 105a of the shower plate 105 into the deposition space 101a.

Furthermore, in the fixed shaft (support shaft) 110 of the present embodiment, a sum of the length in a flow path direction of the shaft gas flow path 135A and the length in a flow path direction of the short gas flow path 105b is set to be equal to the length in a flow path direction of the gas flow path 105a. Therefore, an upper end surface 133 of the adapter 130 can be set to protrude from a surface of the shower plate 105 in the gas introduction space 101b by the same length as a height of the gas flow path space 115.

As a specific method of adjusting the length in a flow path direction, a method of setting a height (a length in the thickness direction of the shower plate 105) of the upper end surface 133 of the adapter 130 by setting a height of a separation distance setting protrusion 134 provided on a lower end surface 132 of the adapter 130, that is, by setting a length of the support shaft 110 in the axial direction can be employed.

At this time, in the fixed shaft (support shaft) 110 of the present embodiment, when a rotation angle at a screw portion between an adapter mounting recess 113 and the adapter 130 and a rotation angle at a screw portion between the shaft mounting recess 105c and a lower end 112 are adjusted to each other, a fitting disposition of the adapter 130 into the adapter mounting recess 113 and a fitting disposition of the lower end 112 into the shaft mounting recess 105c can be set.

Furthermore, in the fixed shaft (support shaft) 110 of the present embodiment, the cross-sectional area of the shaft gas flow path 135A can be set larger than a sum of the cross-sectional areas of the short gas flow paths 105b formed in the shaft mounting recess 105c, and at the same time, the length in a flow path direction of the shaft gas flow path 135A can be set larger than the length in a flow path direction of the shaft gas flow path 135 in the first embodiment.

Similarly, in the present embodiment, as a shape of a shaft gas flow path in a deformed shaft (support shaft) 120, a shape in which only one shaft gas flow path 135A is formed in the adapter 130 is employed. The cross-sectional shape of the shaft gas flow path 135A is not the same as the cross-sectional shape of the gas flow path 105a and can be set to have a larger cross-sectional shape (larger diameter) than the gas flow path 105a.

Also in the configuration of the present embodiment in which the shower plate 105 is supported by the deformed shaft (support shaft) 120, a process gas introduced into the gas introduction space 101b is supplied to the deposition space 101a through the shower plate 105 as shown in FIGS. 9 and 10. At this time, shapes and structures of the shower plate 105 (the gas flow paths 105a, the short gas flow paths 105b, and the shaft mounting recess 105c) and the support shaft 120 are set so that the first conductance of the gas flow paths 105a when the process gas is ejected from the gas flow paths 105a into the deposition space 101a and the second conductance of flow paths when the process gas passes through the support shaft 120 including the shaft gas flow path 135A and is ejected from the short gas flow paths 105b into the deposition space 101a are substantially the same as each other.

Here, the second conductance is a conductance of flow paths when the process gas flows from the gas introduction space 101b to the deposition space 101a through the radial gas flow paths 124, the gas flow path space 126, the shaft gas flow path 135A, the gas flow path space 125, and the short gas flow paths 105b. The second conductance is a conductance that can be obtained by a structure near the lower end 122 of the support shaft 120.

As in the deformed shaft (support shaft) 120 of the first embodiment, shapes of the radial gas flow paths 124, the gas flow path space 126, and the gas flow path space 125 are all set so that a conductance thereof with respect to the process gas ejected into the deposition space 101a can be ignored. Specifically, cross sections of those flow paths can be formed to be increased to such an extent that fluid resistance to the process gas is negligibly small with respect to the shaft gas flow path 135A and the short gas flow paths 105b.

Also, a shape of the shaft gas flow path 135 in the deformed shaft (support shaft) 120 is set and a shape of the short gas flow path 105b in the shower plate 105 is set so that the conductance of the shaft gas flow path 135A and the short gas flow paths 105b, and the conductance of the gas flow paths 105a at a portion other than the connection portion between the support shaft 120 and the shower plate 105 have substantially the same value as each other.

Specifically, the flow path cross-sectional shape of the short gas flow path 105b is set to be equal to the flow path cross-sectional shape of the gas flow path 105a. Also, a cross-sectional area of the shaft gas flow path 135A can be set to be equal to a sum of cross-sectional areas of the short gas flow paths 105b formed in the shaft mounting recess 105c, and the length in a flow path direction of the shaft gas flow path 135A can be set to be equal to the length in a flow path direction of the shaft gas flow path 135 in the first embodiment.

Accordingly, a sum of the length in a flow path direction of the shaft gas flow path 135A and the length in a flow path direction of the short gas flow path 105b can be set to be equal to the length in a flow path direction of the gas flow path 105a.

Therefore, a process gas flowing through the following two flow paths is uniformly ejected in the in-plane direction of the shower plate 105.

(Flow path 7) A flow path of a process gas introduced into the gas introduction space 101b, flowing from the radial gas flow paths 124 to the gas flow path space 126 near the connection portion between the deformed shaft (support shaft) 120 and the shower plate 105, flowing through the shaft gas flow path 135A in the adapter 130, the gas flow path space 125 in the shaft mounting recess 105c, and the short gas flow paths 105b in the shower plate 105, and then ejected from the short gas flow paths 105b into the deposition space 101a.

(Flow path 8) A flow path of a process gas introduced into the gas introduction space 101b and ejected directly from the gas flow paths 105a of the shower plate 105 into the deposition space 101a.

Furthermore, in the deformed shaft (support shaft) 120 of the present embodiment a sum of the length in a flow path direction of the shaft gas flow path 135A and the length in a flow path direction of the short gas flow path 105b is set to be equal to the length in a flow path direction of the gas flow path 105a. Therefore, the upper end surface 133 of the adapter 130 can be set to protrude from the surface of the shower plate 105 in the gas introduction space 101b by the same length as a height of the gas flow path space 125.

As a specific method of adjusting the length in a flow path direction, a method of setting a height (a length in the thickness direction of the shower plate 105) of the upper end surface 133 of the adapter 130 by setting a height of the separation distance setting protrusion 134 provided on the lower end surface 132 of the adapter 130, that is, by setting a length of the deformed shaft (support shaft) 120 in the axial direction can be employed.

At this time, in the deformed shaft (support shaft) 120 of the present embodiment, when a rotation angle at a screw portion between an adapter mounting recess 123 and the adapter 130 and a rotation angle at a screw portion between the shaft mounting recess 105c and the lower end 122 are adjusted to each other, a fitting disposition of the adapter 130 into the adapter mounting recess 123 and a fitting disposition of the lower end 122 into the shaft mounting recess 105c can be set.

Furthermore, in the deformed shaft (support shaft) 120 of the present embodiment, the cross-sectional area of the shaft gas flow path 135A can be set larger than a sum of the cross-sectional areas of the short gas flow paths 105b formed in the shaft mounting recess 105c, and at the same time, the length in a flow path direction of the shaft gas flow path 135A can be set larger than the length in a flow path direction of the shaft gas flow path 135 in the first embodiment.

### EXAMPLES

Hereinafter, an example according to the present disclosure will be described.

A specific example of the present disclosure will be described.

Here, a-Si and SiO depositions were performed using the vacuum processing apparatus shown in FIGS. 1 to 7, and a film thickness distribution was measured.

Specifications in the deposition at this time are shown as below.

Substrate size; 1500×1850 mm

Deposition Conditions

Process gas; during a-Si deposition: Monosilane 1.25 slm, Argon 40 slm

Process gas; during SiO deposition: Monosilane 1.4 slm, nitrogen monoxide 9.5 slm

In-plane density of gas flow paths in shower plate; 20788/m²

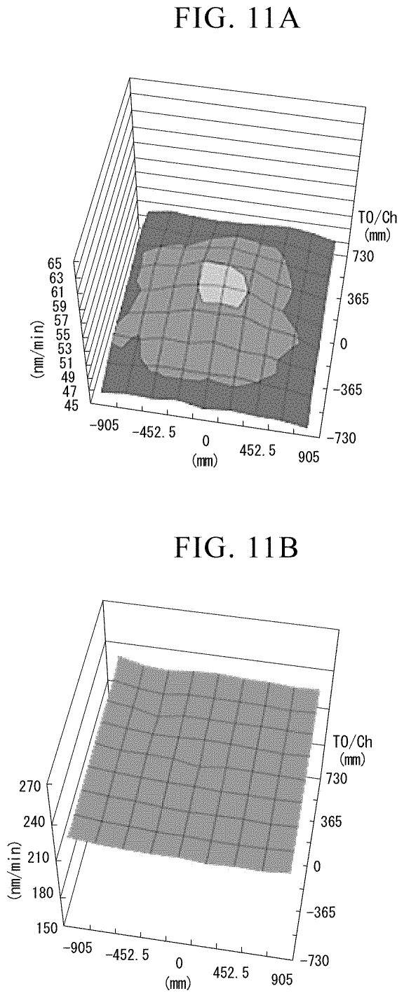

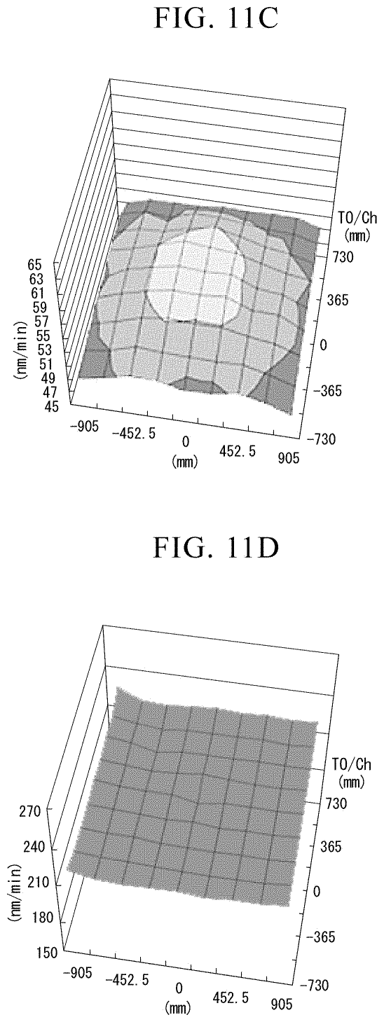

The results are shown in FIGS. 11A and 11B.

At this time, a film thickness distribution of the amorphous silicon film was ±4.4% (FIG. 11A), and a film thickness distribution of the silicon oxide film was ±2.7% (FIG. 11B).

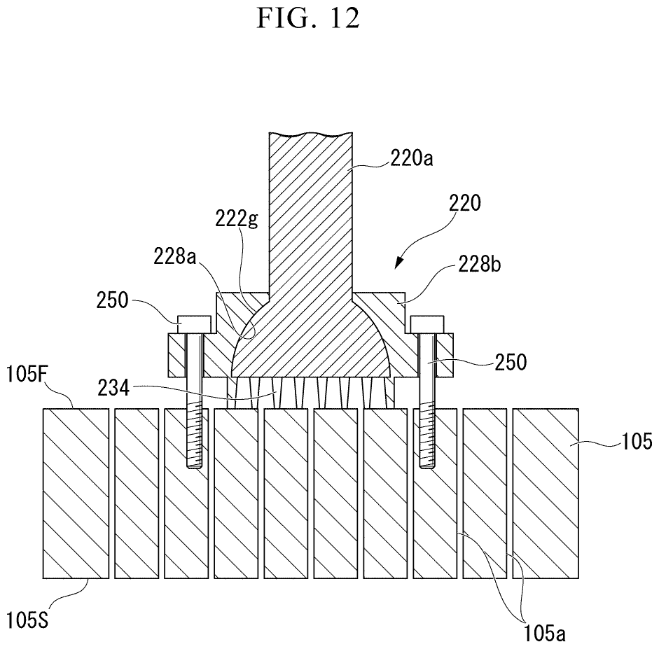

Similarly, for comparison, as shown in FIG. 12, deposition was performed using a Ni alloy and using a deposition apparatus in which all gas flow paths in a shower plate had the same shape (cross-sectional area and length) as each other and an in-plane distribution in the shower plate was uniform.

Furthermore, a deformed shaft (support shaft) 220 shown in FIG. 12 corresponds to the deformed shaft (support shaft) 120, and a separation distance setting protrusion 234 is provided at a lower end thereof and is attached to a shower plate 105 using a mounting bolt 250 made of a Ni alloy.

The separation distance setting protrusion 234, corresponding to the separation distance setting protrusion 134, forms a space serving as a gas flow path. A shaft portion 220a corresponds to the shaft portion 120a, a spherical surface 228a corresponds to the spherical surface 128a, a spherical surface 222g corresponds to the spherical surface 222g, and a lower spherical bush case portion 228b corresponds to the lower spherical bush case portion 128b.

In this example, gas flow paths 105a of the shower plate 105 have the same shape as each other over the entire surface and are uniformly disposed.

The results are shown in FIGS. 11C and 11D. Further, FIG. 11C shows a film thickness distribution of the a-Si film, and FIG. 11C shows a film thickness distribution of the SiO film.

At this time, the film thickness distribution of the amorphous silicon film was ±4.6%, and the film thickness distribution of the silicon oxide film was ±3.4%.

From these results, it is ascertained that the film thickness distribution has been improved when the vacuum processing apparatus of the present disclosure is used.

### DESCRIPTION OF REFERENCE NUMERALS

100 Vacuum processing apparatus
101 Processing chamber
101a Deposition space
101b Gas introduction space
102 Vacuum chamber (chamber)
103 Insulating flange
104 Electrode flange
104a Upper wall
104b Circumferential wall
104c Through hole
105 Shower plate
105a Gas flow path
105b Short gas flow path
105c Shaft mounting recess (recess)
105d Inner surface
115c, 125c Bottom surface (bottom portion)
106 Insulating shield
106a Thermal expansion absorbing space (clearance)
109 Slide seal member
141 Support portion (heater)
142 Process gas supply device (gas supply device)
145 Supporting column
147 RF power supply (high frequency power supply)
148 Vacuum pump (evacuation device)
110 Fixed shaft (support shaft)
111, 121 Upper end
111a, 121a Upper support member
111b, 121b Airtight device
112, 122 Lower end
112a, 122a Outer circumferential surface
112b, 122b End surface
112d Gasket
113, 123 Adapter mounting recess
113a, 123a Inner circumferential surface
113b Upper end surface
114, 124 Radial gas flow path
115, 116, 125, 126 Gas flow path space
120 Deformed shaft (support shaft)
120a Shaft portion
121g, 122g, 127a, 128a Spherical surface
123b Lower end surface
127 Upper spherical bush portion (support angle variable portion)
128 Lower spherical bush portion (support angle variable portion)
128b Lower spherical bush case portion
128c Connection portion
130 Adapter
131 Outer circumferential surface
132 Lower end surface
133 Upper end surface
134 Separation distance setting protrusion
135, 135A Shaft gas flow path

What is claimed is:

1. A vacuum processing apparatus which performs plasma processing, the vacuum processing apparatus comprising:
an electrode flange disposed in a chamber and connected to a high frequency power supply;
a shower plate having a first surface facing the electrode flange and a second surface on a side opposite to the first surface, spaced apart from and facing the electrode flange, and serving as a cathode together with the electrode flange;
a processing chamber which faces the second surface of the shower plate and in which a substrate to be processed is disposed; and
a support shaft connected to the first surface of the shower plate to support the shower plate, wherein
the shower plate is provided with a plurality of gas flow paths that are formed therein, allow a space between the electrode flange and the first surface to communicate with the processing chamber, and have a predetermined conductance, and
a shaft gas flow path extending in an axial direction of the support shaft is provided at a portion in which the support shaft is connected to the shower plate so that the conductance does not change in an in-plane direction of the shower plate.

2. The vacuum processing apparatus according to claim 1, wherein
a recess is formed on the first surface of the shower plate,
the support shaft is fitted into the recess,
the shaft gas flow path is provided at a position inside the recess in the support shaft, and
the support shaft has:
a flow path space positioned above the first surface, provided inside the support shaft, and communicating with the shaft gas flow path; and
a radial gas flow path communicating with the flow path space and extending in a radial direction of the support shaft.

3. The vacuum processing apparatus according to claim 1, wherein
with regard to an in-plane density in the in-plane direction of the shower plate,
an in-plane density of the shaft gas flow paths is the same as an in-plane density of the gas flow paths formed around a portion to which the support shaft is connected in the shower plate, and
the shaft gas flow path has the same conductance as the gas flow paths.

4. The vacuum processing apparatus according to claim 1, wherein
with regard to a length in a thickness direction of the shower plate,
a length of the shaft gas flow path is set to be equal to a length of each of the gas flow paths positioned around the support shaft.

5. The vacuum processing apparatus according to claim 1, wherein
a diameter of the shaft gas flow path is set to be equal to a diameter of the gas flow paths positioned around the support shaft.

6. The vacuum processing apparatus according to claim 2, wherein
the support shaft is fitted into the recess so that an end portion of the support shaft is spaced apart from a bottom portion in the recess of the shower plate.

7. The vacuum processing apparatus according to claim 1 comprises an adapter fitted to the end portion of the support shaft, wherein
the shaft gas flow path is formed in the adapter.

8. The vacuum processing apparatus according to claim 7, wherein
the recess is formed on the first surface of the shower plate,
a short gas flow path allowing the recess to communicate with the processing chamber is formed at a bottom portion of the recess of the shower plate,
the short gas flow path has an opening in the recess,
the adapter has a separation distance setting protrusion provided at an end portion of the adapter in the axial direction of the support shaft, and
the separation distance setting protrusion is in contact with the bottom portion of the recess to cause the adapter to be spaced apart from the bottom portion of the recess so that a space is formed between the shaft gas flow path and the opening of the short gas flow path.

9. The vacuum processing apparatus according to claim 1, wherein
the support shaft comprises a support angle variable portion which is able to obliquely support the shower plate in response to thermal deformation that occurs when a temperature of the shower plate is raised and lowered.

10. The vacuum processing apparatus according to claim 9, wherein
the support angle variable portion is a spherical bush provided on both end sides of the support shaft.

11. A support shaft used in a vacuum processing apparatus that performs plasma processing, wherein
the vacuum processing apparatus comprises:
an electrode flange disposed in a chamber and connected to a high frequency power supply;
a shower plate having a first surface facing the electrode flange and a second surface on a side opposite to the first surface, spaced apart from and facing the electrode flange, and serving as a cathode together with the electrode flange; and
a processing chamber which faces the second surface of the shower plate and in which a substrate to be processed is disposed,
the shower plate is provided with a plurality of gas flow paths that are formed therein, allow a space between the electrode flange and the first surface to communicate with the processing chamber, and have a predetermined conductance,
the support shaft is connected to the first surface of the shower plate to support the shower plate, and
a shaft gas flow path extending in an axial direction of the support shaft is provided at a portion in which the support shaft is connected to the shower plate so that the conductance does not change in an in-plane direction of the shower plate.
